(19) United States
(12) Patent Application Publication
(10) Pub. No.: US 2024/0234165 A9
(43) Pub. Date: Jul. 11, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Yuseon HEO, Suwon-si (KR); Junhyeong Park, Suwon-si (KR); Jieun Park, Suwon-si (KR); Jihye Shim, Suwon-si (KR); Jiyoung Lee, Suwon-si (KR)

(73) Assignee: SAMSUNG ELECTRONICS CO., LTD., Suwon-si (KR)

(21) Appl. No.: 18/381,905

(22) Filed: Oct. 19, 2023

(30) Foreign Application Priority Data
Oct. 21, 2022 (KR) 10-2022-0136830

(51) Int. Cl. H01L 21/48; H01L 23/31; H01L 23/498; H01L 25/18; H10B 80/00

(52) U.S. Cl. CPC H01L 21/4857; H01L 23/3128; H01L 23/49838; H01L 25/18; H10B 80/00; H01L 24/04

(57) ABSTRACT

Provided is a method of manufacturing a semiconductor package, the method including forming a first wiring structure, coating a high transmittance photoresist on the first wiring structure a plurality of number of times, forming a plurality of openings by exposing and developing the high transmittance photoresist, forming a plurality of conductive posts by filling the plurality of openings with a conductive material, removing the high transmittance photoresist, disposing a semiconductor chip on the first wiring structure, forming an encapsulant surrounding the semiconductor chip and the plurality of conductive posts, and forming a second wiring structure on the encapsulant, wherein the light transmittance of the high transmittance photoresist at a portion where the first wiring structure and the high transmittance photoresist contact each other is greater than or equal to 3.2%.

### CROSS-REFERENCE TO RELATED APPLICATION

This application claims priority to Korean Patent Application No. 10-2022-0136830, filed on Oct. 21, 2022, in the Korean Intellectual Property Office, the disclosure of which is incorporated by reference herein in its entirety.

### BACKGROUND

Embodiments of the present disclosure relate to a semiconductor package and a method of manufacturing the same, and more particularly, to a fan-out semiconductor package and a method of manufacturing the same.

Due to the rapid developments of the electronics industry and demands of users, electronic devices are becoming smaller and lighter, having more functions, and having higher capacity, and thus, highly integrated semiconductor chips are needed. Therefore, a semiconductor package including a highly integrated semiconductor chip having an increased number of connection terminals for input/output (I/O) and securing connection reliability has been devised. For example, to prevent interference between connection terminals, a fan-out semiconductor package having an increased distance between connection terminals is being developed.

### SUMMARY

One or more embodiments provide a semiconductor package with improved reliability and productivity due to accurate formation of conductive posts having a high aspect ratio according to design rules using a high transmittance photoresist and a method of manufacturing the semiconductor package.

In addition, the technical goals to be achieved by embodiments are not limited to the technical goals mentioned above, and other technical goals may be clearly understood by one of ordinary skill in the art from the following descriptions.

According to an aspect of an embodiment, there is provided a method of manufacturing a semiconductor package, the method including forming a first wiring structure, including a plurality of first wiring patterns that include a plurality of first connection pads, and a first insulation layer surrounding the plurality of first wiring patterns, the first wiring structure including a chip mounting region and a peripheral region adjacent to the chip mounting region, coating a high transmittance photoresist on the first wiring structure a plurality of number of times, forming a plurality of openings in the peripheral region by exposing and developing the high transmittance photoresist, forming a plurality of conductive posts connected to the plurality of first connection pads in the peripheral region by filling the plurality of openings with a conductive material, removing the high transmittance photoresist, disposing a semiconductor chip in the chip mounting region on the first wiring structure, forming an encapsulant surrounding the semiconductor chip and the plurality of conductive posts, and forming a second wiring structure on the encapsulant, the second wiring structure including a plurality of second wiring patterns that include a plurality of second connection pads electrically connected to the plurality of conductive posts and a second insulation layer surrounding the plurality of second wiring patterns, wherein light transmittance of the high transmittance photoresist is equal to or greater than 3.2% at a portion where the first wiring structure contacts the high transmittance photoresist.

According to another aspect of an embodiment, there is provided a method of manufacturing a semiconductor package, the method including forming a first wiring structure including a chip mounting region and a peripheral region adjacent to the chip mounting region, forming a first photoresist layer by first coating and baking a high transmittance photoresist on the first wiring structure, forming a second photoresist layer by second coating and baking the high transmittance photoresist on the first photoresist layer, forming a third photoresist layer by third coating and baking the high transmittance photoresist on the second photoresist layer, forming a plurality of openings in the peripheral region by exposing and developing the first photoresist layer, the second photoresist layer, and the third photoresist layer, forming a plurality of conductive posts by filling the plurality of openings with a conductive material through a single plating process, removing the first photoresist layer, the second photoresist layer, and the third photoresist layer, disposing a semiconductor chip in the chip mounting region on the first wiring structure, forming an encapsulant surrounding the semiconductor chip and the plurality of conductive posts, and forming a second wiring structure on the encapsulant, wherein light transmittance of the first photoresist layer is greater than or equal to 3.2% at a portion where the first wiring structure contacts the first photoresist layer.

According to another aspect of an embodiment, there is provided a semiconductor package including a first redistribution structure including a plurality of first redistribution patterns including a plurality of first bottom surface connection pads and a plurality of first top surface connection pads, and a first redistribution insulation layer surrounding the plurality of first redistribution patterns, a first semiconductor chip on a first chip mounting region on the first redistribution structure, a second redistribution structure on the first semiconductor chip and the first redistribution structure, the second redistribution structure including a plurality of second redistribution patterns including a plurality of second bottom surface connection pads and a plurality of second top surface connection pads, and a second redistribution insulation layer surrounding the plurality of second redistribution patterns, a second semiconductor chip on a second chip mounting region on the second redistribution structure, a plurality of conductive posts adjacent to the first semiconductor chip and connecting some of the plurality of first top surface connection pads to some of the plurality of second bottom surface connection pads, and an encapsulant filling a space between the first redistribution structure and the second redistribution structure and surrounding the plurality of conductive posts and the first semiconductor chip, wherein each of the plurality of conductive posts includes a body portion having a constant horizontal cross-sectional area, and a bottom portion having a varying horizontal cross-sectional area, and wherein a top surface of the body portion has a first diameter and a bottom surface of the bottom portion has a second diameter that is different from the first diameter.

### BRIEF DESCRIPTION OF DRAWINGS

Embodiments will be more clearly understood from the following detailed description taken in conjunction with the accompanying drawings in which:

FIG. 1 is a cross-sectional view of components of a semiconductor package according to an embodiment;

FIGS. 2A, 2B, and 2C are enlarged cross-sectional views of various embodiments of a portion CX of FIG. 1;

FIGS. 3A, 3B, and 3C are enlarged cross-sectional views of other embodiments of a portion CX of FIG. 1;

FIG. 4 is a flowchart of a method of manufacturing a semiconductor package, according to an embodiment;

FIGS. 5, 6, 7, 8, 9, 10, 11, 12, 13, 14, 15, and 16 are diagrams showing a method of manufacturing a semiconductor package according to an embodiment; and

FIG. 17 is a diagram showing a configuration of a semiconductor package according to an embodiment.

### DETAILED DESCRIPTION OF EMBODIMENTS

Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

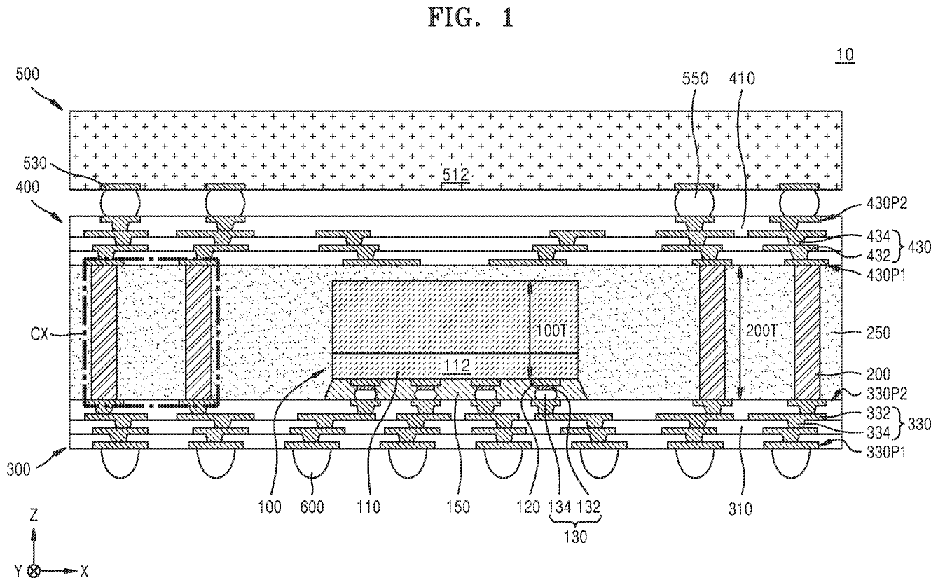

FIG. 1 is a cross-sectional view of components included a semiconductor package according to an embodiment.

Referring to FIG. 1, a semiconductor package 10 may include a first semiconductor chip 100, conductive posts 200 arranged around and adjacent to the first semiconductor chip 100, a first wiring structure 300 disposed below the first semiconductor chip 100, a second wiring structure 400 disposed over the first semiconductor chip 100, and a second semiconductor chip 500 disposed above the second wiring structure 400.

The semiconductor package 10 may have a package-on-package (PoP) structure. In detail, the semiconductor package 10 may be a fan-out semiconductor package in which the horizontal width and the horizontal area of the first wiring structure 300 are greater than the horizontal width and the horizontal area of the first semiconductor chip 100. According to some embodiments, the semiconductor package 10 may be a fan out wafer level package (FOWLP) or a fan out panel level package (FOPLP).

According to some embodiments, the first wiring structure 300 and the second wiring structure 400 may be formed through a redistribution process. Therefore, the first wiring structure 300 and the second wiring structure 400 may be respectively referred to as a first redistribution structure and a second redistribution structure or may be respectively referred to as a lower redistribution structure and an upper redistribution structure.

The first wiring structure 300 may include a first redistribution insulation layer 310 and a plurality of first redistribution patterns 330. The first redistribution insulation layer 310 may cover the plurality of first redistribution patterns 330. According to some embodiments, the first wiring structure 300 may include a plurality of stacked first redistribution insulation layers 310. The first redistribution insulation layer 310 may include, for example, photo imageable dielectric (PID) or photosensitive polyimide (PSPI).

The plurality of first redistribution patterns 330 may include a plurality of first redistribution line patterns 332 and a plurality of first redistribution vias 334. For example, the plurality of first redistribution patterns 330 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof. However, embodiments are not limited thereto.

The plurality of first redistribution line patterns 332 may be arranged on at least one of the top surface and the bottom surface of the first redistribution insulation layer 310. For example, when the first wiring structure 300 includes a plurality of stacked first redistribution insulation layers 310, the plurality of first redistribution line patterns 332 may be arranged on the top surface of the uppermost first redistribution insulation layer 310, the bottom surface of the lowermost first redistribution insulation layer 310, and between first redistribution insulation layers 310 adjacent to each other.

The plurality of first redistribution vias 334 may penetrate through the first redistribution insulation layer 310 and be connected to some of the plurality of first redistribution line patterns 332. According to some embodiments, the plurality of first redistribution vias 334 may have a tapered shape in which the horizontal width thereof increases upward in the vertical direction.

According to some embodiments, some of the plurality of first redistribution line patterns 332 may be formed together and integrated with some of the plurality of first redistribution vias 334. For example, a first redistribution line pattern 332 and a first redistribution via 334 contacting the bottom surface of the first redistribution line pattern 332 may be formed together and integrated with each other.

From among the plurality of first redistribution patterns 330, some arranged adjacent to the bottom surface of the first wiring structure 300 may be referred to as a plurality of first bottom surface connection pads 330P1, and some others arranged adjacent to the top surface of the first wiring structure 300 may be referred to as a plurality of first top surface connection pads 330P2. For example, the plurality of first bottom surface connection pads 330P1 may be first redistribution line patterns 332 arranged adjacent to the bottom surface of the first wiring structure 300, and the plurality of first top surface connection pads 330P2 may be first redistribution line patterns 332 arranged adjacent to the top surface of the first wiring structure 300.

A plurality of external connection terminals 600 may be attached to the plurality of first bottom surface connection pads 330P1, respectively. The plurality of external connection terminals 600 may connect the semiconductor package 10 externally. According to some embodiments, the plurality of external connection terminals 600 may include solder bumps or solder balls. A plurality of chip connecting members 130 may be attached to some of the plurality of first top surface connection pads 330P2, and a plurality of conductive posts 200 may be attached to the other first top surface connection pads 330P2.

The plurality of first top surface connection pads 330P2 may be arranged on the top surface of the first redistribution insulation layer 310. For example, when the first wiring structure 300 includes a plurality of stacked first redistribution insulation layers 310, the plurality of first top surface connection pads 330P2 may be arranged on the top surface of the uppermost first redistribution insulation layer 310. According to some embodiments, the top surface of the plurality of first top surface connection pads 330P2 may be coplanar with the top surface of the uppermost first redistribution insulation layer 310.

At least one first semiconductor chip 100 may be mounted on the first wiring structure 300. For example, one first semiconductor chip 100 or a plurality of first semiconductor chips 100 may be provided. The first semiconductor chip 100 may include a semiconductor substrate 110 having an active surface and an inactive surface facing each other, a semiconductor device 112 formed on the active surface of the semiconductor substrate 110, and a plurality of chip pads 120 arranged on a first surface of the first semiconductor chip 100. For example, the first semiconductor chip 100 may have a thickness 100T that is equal to or greater than about 150 μm.

The first surface and a second surface of the first semiconductor chip 100 face each other, and the second surface of the first semiconductor chip 100 may be the inactive surface of the semiconductor substrate 110. Since the active surface of the semiconductor substrate 110 is adjacent to the first surface of the first semiconductor chip 100, the active surface of the semiconductor substrate 110 and the first surface of the first semiconductor chip 100 are not distinguished from one another in the drawing.

According to some embodiments, the first semiconductor chip 100 has a face down arrangement in which the first surface of the first semiconductor chip 100 faces the first wiring structure 300 and may be mounted on the top surface of the first wiring structure 300. In this case, the first surface of the first semiconductor chip 100 may be referred to as the bottom surface of the first semiconductor chip 100, and the second surface of the first semiconductor chip 100 may be referred to as the top surface of the first semiconductor chip 100.

The plurality of chip connecting members 130 may be provided between the plurality of chip pads 120 of the first semiconductor chip 100 and some of the plurality of first top surface connection pads 330P2 of the first wiring structure 300. For example, the plurality of chip connecting members 130 may each be a solder ball or a micro bump. The first semiconductor chip 100 and the first redistribution patterns 330 of the first wiring structure 300 may be electrically connected to each other through the plurality of chip connecting members 130. The plurality of chip connecting members 130 may each include an under bump metal (UBM) layer 132 disposed on a chip pad 120 and a conductive connection member 134 covering the UBM layer 132. The plurality of chip connecting members 130 may include, for example, copper (Cu), aluminum (Al), silver (Ag), tin (Tin), gold (Au), or solder. However, embodiments are not limited thereto.

The semiconductor substrate 110 may include, for example, a semiconductor material such as silicon (Si) or germanium (Ge). According to another embodiment, the semiconductor substrate 110 may include a compound semiconductor material such as silicon carbide (SiC), gallium arsenide (GaAs), indium arsenide (InAs), and indium phosphide (InP). The substrate 110 may include a well doped with an impurity, which is a conductive region. The semiconductor substrate 110 may have various device isolation structures such as a shallow trench isolation (STI) structure.

The semiconductor device 112 including a plurality of individual devices of various types may be formed on the active surface of the semiconductor substrate 110. The plurality of individual devices may be electrically connected to the conductive region of the semiconductor substrate 110. The semiconductor device 112 may further include conductive wires or conductive plugs electrically connecting the plurality of individual devices to the conductive region of the semiconductor substrate 110. Also, the individual devices may each be electrically separated from other neighboring individual devices by an insulation film.

According to some embodiments, the first semiconductor chip 100 may include a logic device. For example, the first semiconductor chip 100 may be a central processing unit chip, a graphics processing unit chip, or an application processor chip. According to other embodiments, when the semiconductor package 10 includes a plurality of first semiconductor chips 100, one of the plurality of first semiconductor chips 100 may be a central processing unit chip, a graphics processing unit chip, or an application processor chip, and another one of the plurality of first semiconductor chips 100 may be a memory semiconductor chip including a memory device.

For example, the memory device may be a non-volatile memory device such as a flash memory, phase-change random access memory (PRAM), magnetic random access memory (MRAM), ferroelectric random access memory (FeRAM), or resistive random access memory (RRAM). According to some embodiments, the memory device may be a volatile memory device such as dynamic random access memory (DRAM) or static random access memory (SRAM).

The second wiring structure 400 may include a second redistribution insulation layer 410 and a plurality of second redistribution patterns 430. The second redistribution insulation layer 410 may be provided on and cover the plurality of second redistribution patterns 430. The second redistribution insulation layer 410 may include, for example, PID or PSPI.

According to some embodiments, the second wiring structure 400 may include a plurality of stacked second redistribution insulation layers 410. The plurality of second redistribution patterns 430 may include a plurality of second redistribution line patterns 432 and a plurality of second redistribution vias 434. The plurality of second redistribution patterns 430 may include a metal or a metal alloy. According to some embodiments, the plurality of second redistribution patterns 430 may be formed by stacking a metal or a metal alloy on a seed layer.

The plurality of second redistribution line patterns 432 may be arranged on at least one of the top surface and the bottom surface of the second redistribution insulation layer 410. For example, when the second wiring structure 400 includes a plurality of stacked second redistribution insulation layers 410, the plurality of second redistribution line patterns 432 may be arranged on the top surface of the uppermost second redistribution insulation layer 410, the bottom surface of the lowermost second redistribution insulation layer 410, and between second redistribution insulation layers 410 adjacent to each other.

From among the plurality of second redistribution patterns 430, second redistribution patterns 430 arranged adjacent to the bottom surface of the second wiring structure 400 may be referred to as a plurality of second bottom surface connection pads 430P1, and second redistribution patterns 430 arranged adjacent to the top surface of the second wiring structure 400 may be referred to as a plurality of second top surface connection pads 430P2. For example, the plurality of second bottom surface connection pads 430P1 may be second redistribution patterns 430 arranged adjacent to the bottom surface of the second wiring structure 400 from among the plurality of second redistribution line patterns 432, and the plurality of second top surface connection pads 430P2 may be second redistribution patterns 430 arranged adjacent to the top surface of the second wiring structure 400 from among the plurality of second redistribution line patterns 432. According to other embodiments, the plurality of second bottom surface connection pads 430P1 may be second redistribution vias 434 arranged adjacent to the bottom surface of the second wiring structure 400.

The second semiconductor chip 500 may include a second semiconductor device 512 and a plurality of second pads 530. The second semiconductor chip 500 may be electrically connected to the second wiring structure 400 through a plurality of internal connection terminals 550 between the plurality of second pads 530 and the plurality of second top surface connection pads 430P2. The second semiconductor chip 500 may be mounted on the second wiring structure 400, such that the plurality of second pads 530 face the second wiring structure 400.

According to some embodiments, the second semiconductor chip 500 may be electrically connected to the plurality of first redistribution patterns 330 of the first wiring structure 300 through the plurality of internal connection terminals 550 attached to the plurality of second pads 530, the plurality of second redistribution patterns 430, and the plurality of conductive posts 200.

According to some embodiments, the second semiconductor device 512 may be a memory device. For example, the memory device may be a non-volatile memory device such as flash memory, PRAM, MRAM, FeRAM, or RRAM. According to some embodiments, the memory device may be a volatile memory device such as DRAM or SRAM.

The plurality of second bottom surface connection pads 430P1 may be arranged on the bottom surface of the second redistribution insulation layer 410. For example, when the second wiring structure 400 includes a plurality of stacked second redistribution insulation layers 410, the plurality of second bottom surface connection pads 430P1 may be arranged on the bottom surface of the lowermost second redistribution insulation layer 410. According to some embodiments, the bottom surfaces of the plurality of second bottom surface connection pads 430P1 may be coplanar with the bottom surface of the lowermost second redistribution insulation layer 410.

The plurality of second top surface connection pads 430P2 may be arranged on the top surface of the second redistribution insulation layer 410. For example, when the second wiring structure 400 includes a plurality of stacked second redistribution insulation layers 410, the plurality of second top surface connection pads 430P2 may be arranged on the top surface of the topmost second redistribution insulation layer 410. According to some embodiments, the top surfaces of the plurality of second top surface connection pads 430P2 may be coplanar with the bottom surface of the topmost second redistribution insulation layer 410.

The plurality of second redistribution vias 434 may penetrate through the second redistribution insulation layer 410 and be connected to some of the plurality of second redistribution line patterns 432. According to some embodiments, some of the plurality of second redistribution line patterns 432 may be formed integrally with some of the plurality of second redistribution vias 434. For example, a second redistribution line pattern 432 and a second redistribution via 434 contacting the bottom surface of the second redistribution line pattern 432 may be formed integrally with each other.

According to some embodiments, the plurality of second redistribution vias 434 may have a tapered shape in which the horizontal width thereof decreases downward in the vertical direction. For example, the plurality of first redistribution vias 334 and the plurality of second redistribution vias 434 may extend in the same direction and horizontal widths thereof may decrease in the same direction. However, embodiments are not limited thereto.

For example, the first redistribution insulation layer 310, the first redistribution patterns 330, the first redistribution line patterns 332, and the first redistribution vias 334 may be referred to as a first insulation layer, first wiring patterns, first wiring line patterns, and first wiring vias, respectively. Also, the second redistribution insulation layer 410, the second redistribution patterns 430, the second redistribution line patterns 432, and the second redistribution vias 434 may be referred to as a second insulation layer, second wiring patterns, second wiring line patterns, and second wiring vias, respectively.

An encapsulant 250 on the top surface of the first wiring structure 300 may cover the first semiconductor chip 100. The encapsulant 250 may fill a space between the first wiring structure 300 and the second wiring structure 400. For example, the encapsulant 250 may have a thickness from about 150 μm to about 500 μm. For example, the encapsulant 250 may be a molding member including an epoxy mold compound (EMC). The encapsulant 250 may further include a filler.

According to some embodiments, an underfill layer 150 surrounding the plurality of chip connecting members 130 may be provided between the first semiconductor chip 100 and the first wiring structure 300. According to some embodiments, the underfill layer 150 may fill a space between the first semiconductor chip 100 and the first wiring structure 300 and may cover lower portions of side surfaces of the first semiconductor chip 100. The underfill layer 150 may be formed through, for example, a capillary underfill process and may include an epoxy resin.

According to some embodiments, side surfaces of the first wiring structure 300, side surfaces of the encapsulant 250, and side surfaces of the second wiring structure 400 may be aligned with one another in the vertical direction to be coplanar with one another.

The plurality of conductive posts 200 through the encapsulant 250 may electrically interconnect the first wiring structure 300 and the second wiring structure 400. The encapsulant 250 may surround the plurality of conductive posts 200.

The plurality of conductive posts 200 may be provided between the first wiring structure 300 and the second wiring structure 400 and spaced apart from the first semiconductor chip 100 in a horizontal direction. For example, the plurality of conductive posts 200 may be spaced apart from the first semiconductor chip 100 in a horizontal direction and arranged around the first semiconductor chip 100 in a peripheral region of the first wiring structure 300.

The plurality of conductive posts 200 may be provided between the plurality of first top surface connection pads 330P2 and the plurality of second bottom surface connection pads 430P1. The bottom surfaces of the plurality of conductive posts 200 may be electrically connected to the plurality of first redistribution patterns 330 by contacting the plurality of first top surface connection pads 330P2 of the first wiring structure 300, and the top surface of the conductive posts 200 may be electrically connected to the plurality of second redistribution patterns 430 by contacting the plurality of second bottom surface connection pads 430P1 of the second wiring structure 400.

For example, a thickness 200T of each of the plurality of conductive posts 200 may be from about 200 om to about 500 om, and the horizontal width of each of the plurality of conductive posts 200 may be from about 120 om to about 200 om. The aspect ratio of each of the plurality of conductive posts 200, i.e., a ratio of the height with respect to the horizontal width, may be greater than 1. According to some embodiments, the plurality of conductive posts 200 may include copper (Cu) or a Cu alloy, but the embodiments are not limited thereto.

The bottom surfaces of the plurality of conductive posts 200 may contact the top surfaces of the first top surface connection pads 330P2, respectively. The top surfaces of the plurality of conductive posts 200 may contact the bottom surfaces of the second bottom surface connection pads 430P1, respectively.

According to some embodiments, the horizontal width and the horizontal area of a first top surface connection pad 330P2 contacting a conductive post 200 may be greater than the horizontal width and the horizontal area of the conductive post 200. For example, the entire bottom surface of the conductive post 200 may contact the top surface of the first top surface connection pad 330P2, but a portion of the top surface of the first top surface connection pad 330P2 may not contact the conductive post 200.

According to some embodiments, the horizontal width and the horizontal area of a second bottom surface connection pad 430P1 contacting the conductive post 200 may be greater than the horizontal width and the horizontal area of the conductive post 200. For example, the entire top surface of the conductive post 200 may contact the bottom surface of the second bottom surface connection pad 430P1, but a portion of the bottom surface of the second bottom surface connection pad 430P1 may not contact the conductive post 200.

Due to the rapid developments of the electronics industry and demands of users, electronic devices are becoming smaller and lighter, having more functions, and having higher capacity, and thus, highly integrated semiconductor chips are demanded. Therefore, to improve heat dissipation characteristics of the first semiconductor chip 100, the thickness 100T of the first semiconductor chip 100 is continuously increasing. As such, the increase in the thickness 100T of the first semiconductor chip 100 also affects the thickness 200T of the plurality of conductive posts 200 electrically interconnecting the first wiring structure 300 to the second wiring structure 400.

An exposure process using a photoresist and a development process are used to form conductive posts. Therefore, as the height of conductive posts increases, the thickness of the photoresist also needs to be increased. However, at a thickness equal to greater than a certain level, the light transmittance of the photoresist is significantly reduced, and thus, it is difficult to manufacture a conductive post satisfying an increased thickness through a single exposure process, a single development process, and a single plating process.

As a result, to manufacture a conductive post having an increased thickness, the manufacturing process of the conductive post needs to be performed twice or a greater number of times. For example, an exposure process and a development process are performed twice, and a double plating process is used accordingly. However, this may cause addition of a considerable number of operations, thereby deteriorating productivity.

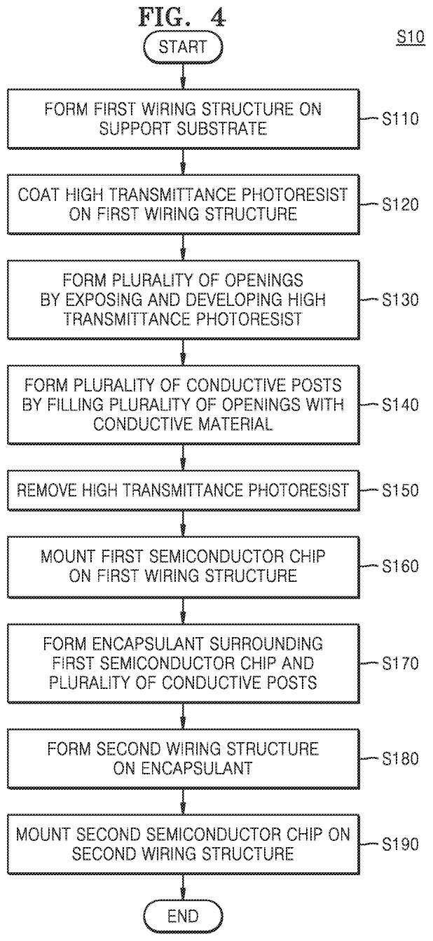

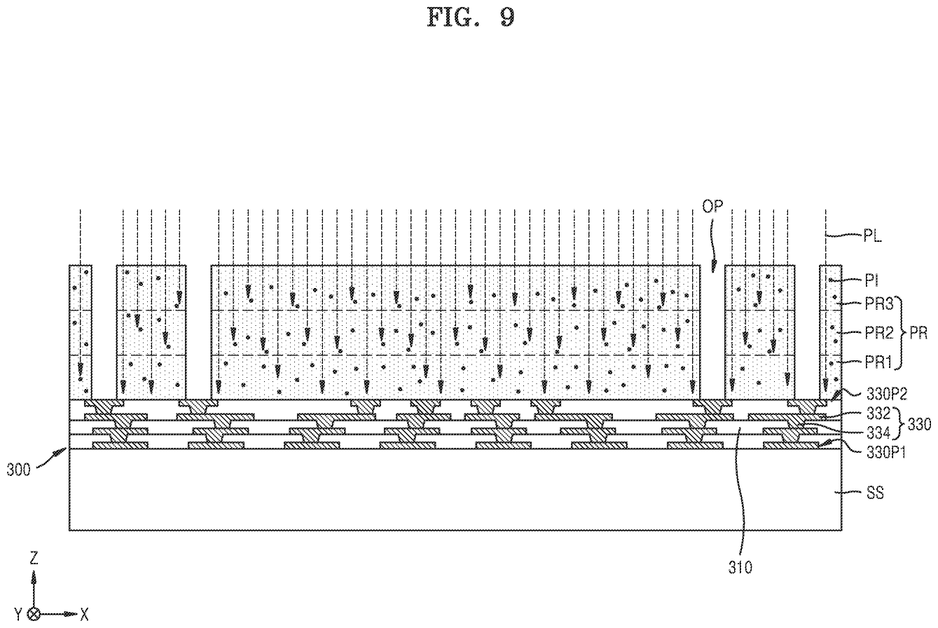

To solve this problem, according to a method S10 (refer to FIG. 4) of manufacturing the semiconductor package 10 to be described later, the plurality of conductive posts 200 having a high aspect ratio may be more accurately formed according to design rules through a single exposure process, a single development process, and a single plating process by using a high transmittance photoresist PR (refer to FIG. 9).

Ultimately, according to the method S10 (refer to FIG. 4) of manufacturing a semiconductor package using a high transmittance photoresist PR (refer to FIG. 9), the reliability and productivity of the semiconductor package 10 may be improved.

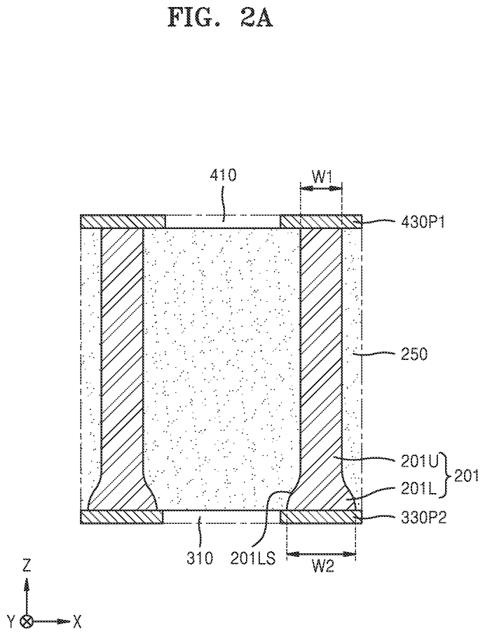

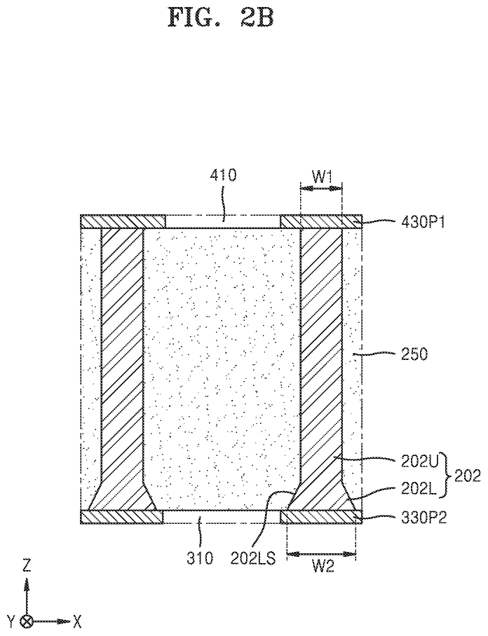

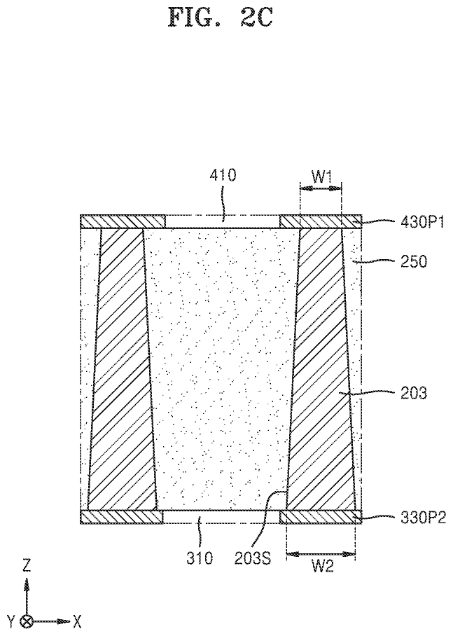

FIGS. 2A to 2C are enlarged cross-sectional views of various embodiments of a portion CX of FIG. 1.

In common in FIGS. 2A to 2C, the top surfaces of conductive posts 201, 202, and 203 may each have a first diameter W1, and the bottom surfaces of the conductive posts 201, 202, and 203 may each have a second diameter W2. The second diameter W2 may be greater than 1.0 times the first diameter W1 and less than 1.3 times the first diameter W1. For example, a difference between the first diameter W1 and the second diameter W2 may be up to about 30%. This characteristic may be due to the high transmittance photoresist PR (refer to FIG. 9) used in a method S10 (refer to FIG. 4) of manufacturing a semiconductor package to be described later.

Referring to FIG. 2A, conductive posts 201 may have rotational symmetry around the axis in a vertical direction (Z direction). However, the embodiments are not limited thereto, and most of the conductive posts 201 may have a rectangular horizontal cross-sectional shape.

A conductive post 201 may include a body portion 201U and a bottom portion 201L. The top surface of the body portion 201U may contact the bottom surface of the second bottom surface connection pad 430P1, and the bottom surface of the bottom portion 201L may contact the top surface of the first top surface connection pad 330P2.

The body portion 201U may have a cylindrical shape. The horizontal cross-sectional area of the body portion 201U in the vertical direction (Z direction) may be substantially constant. Here, the horizontal cross-sectional area refers to a cross-sectional area perpendicular to the vertical direction (Z direction) (i.e., the normal line is parallel to the vertical direction).

The horizontal cross-sectional area of the bottom portion 201L may vary. The horizontal cross-sectional area of the bottom portion 201L may increase toward the first top surface connection pad 330P2. For example, the bottom portion 201L may include a rounded sidewall 201LS, and the rounded sidewall 201LS may have a convex shape.

Referring to FIG. 2B, conductive posts 202 may have rotational symmetry around the axis in a vertical direction (Z direction). However, the embodiments are not limited thereto, and most of the conductive posts 202 may have a rectangular horizontal cross-sectional shape.

A conductive post 202 may include a body portion 202U and a bottom portion 202L. The top surface of the body portion 202U may contact the bottom surface of the second bottom surface connection pad 430P1, and the bottom surface of the bottom portion 202L may contact the top surface of the first top surface connection pad 330P2.

The body portion 202U may have a cylindrical shape. The horizontal cross-sectional area of the body portion 202U in the vertical direction (Z direction) may be substantially constant.

The horizontal cross-sectional area of the bottom portion 202L may vary. The horizontal cross-sectional area of the bottom portion 202L may increase toward the first top surface connection pad 330P2. For example, the bottom portion 202L may have a truncated cone-like shape, and the bottom portion 202L may include a sidewall 202LS inclined outward.

Referring to FIG. 2C, conductive posts 203 may have rotational symmetry around the axis in a vertical direction (Z direction). A conductive post 203 may have a trapezoidal horizontal cross-sectional shape.

The top surface of the conductive post 203 may contact the bottom surface of the second bottom surface connection pad 430P1, and the bottom surface of the conductive post 203 may contact the top surface of the first top surface connection pad 330P2.

The horizontal cross-sectional area of the conductive post 203 may vary. The horizontal cross-sectional area of the conductive post 203 may increase toward the first top surface connection pad 330P2. For example, the conductive post 203 may have a truncated cone-like shape, and the conductive post 203 may include a sidewall 203S inclined outward.

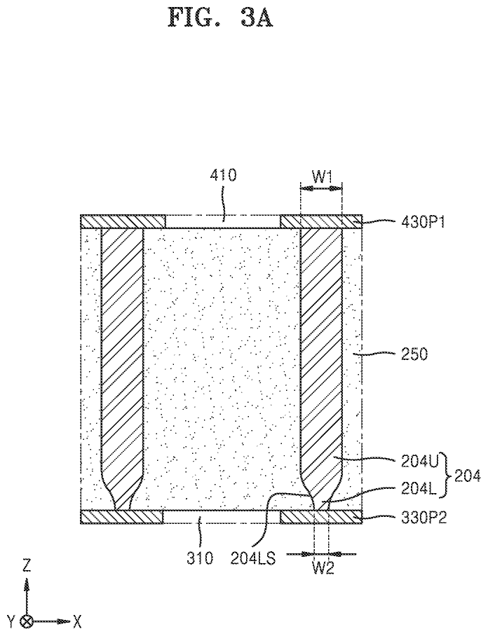

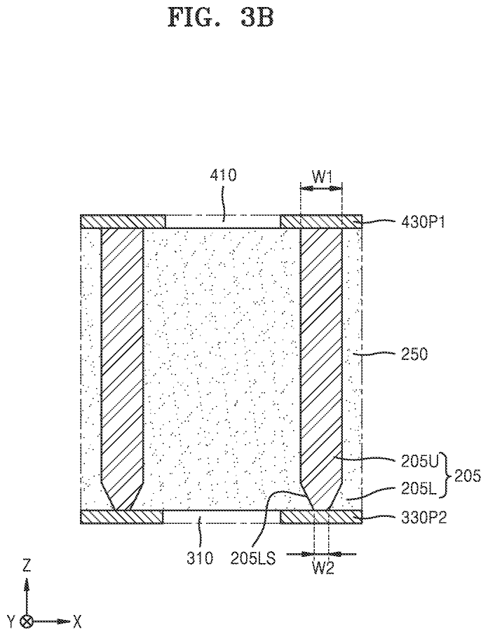

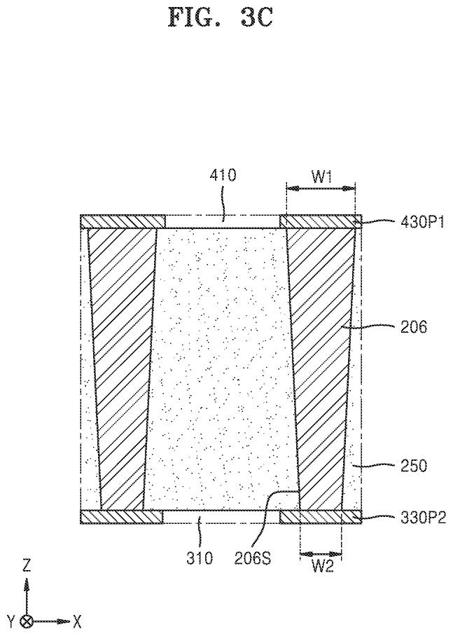

FIGS. 3A to 3C are enlarged cross-sectional views of other embodiments of a portion CX of FIG. 1.

As illustrated in FIGS. 3A to 3C, the top surfaces of conductive posts 204, 205, and 206 may each have the first diameter W1, and the bottom surfaces of the conductive posts 204, 205, and 206 may each have the second diameter W2. The second diameter W2 may be greater than 0.7 times the first diameter W1 and less than 1.0 times the first diameter W1. For example, a difference between the first diameter W1 and the second diameter W2 may be up to about −30%. This characteristic may be due to the high transmittance photoresist PR (refer to FIG. 9) used in a method S10 (refer to FIG. 4) of manufacturing a semiconductor package to be described later.

Referring to FIG. 3A, conductive posts 204 may have rotational symmetry around the axis in a vertical direction (Z direction). However, the embodiments are not limited thereto, and most of the conductive posts 204 may have a rectangular horizontal cross-sectional shape.

A conductive post 204 may include a body portion 204U and a bottom portion 204L. The top surface of the body portion 204U may contact the bottom surface of the second bottom surface connection pad 430P1, and the bottom surface of the bottom portion 204L may contact the top surface of the first top surface connection pad 330P2.

The body portion 204U may have a cylindrical shape. The horizontal cross-sectional area of the body portion 204U in the vertical direction (Z direction) may be substantially constant.

The horizontal cross-sectional area of the bottom portion 204L may vary. The horizontal cross-sectional area of the bottom portion 204L may decrease toward the first top surface connection pad 330P2. For example, the bottom portion 204L may include a rounded sidewall 204LS, and the rounded sidewall 204LS may have a concave shape.

Referring to FIG. 3B, conductive posts 205 may have rotational symmetry around the axis in a vertical direction (Z direction). However, the embodiments are not limited thereto, and most of the conductive posts 205 may have a rectangular horizontal cross-sectional shape.

A conductive post 205 may include a body portion 205U and a bottom portion 205L. The top surface of the body portion 205U may contact the bottom surface of the second bottom surface connection pad 430P1, and the bottom surface of the bottom portion 205L may contact the top surface of the first top surface connection pad 330P2.

The body portion 205U may have a cylindrical shape. The horizontal cross-sectional area of the body portion 205U in the vertical direction (Z direction) may be substantially constant.

The horizontal cross-sectional area of the bottom portion 205L may vary. The horizontal cross-sectional area of the bottom portion 205L may decrease toward the first top surface connection pad 330P2. For example, the bottom portion 205L may have an inverted truncated cone-like shape, and the bottom portion 205L may include a sidewall 205LS inclined inward.

Referring to FIG. 3C, conductive posts 206 may have rotational symmetry around the axis in a vertical direction (Z direction). A conductive post 206 may have an inverted trapezoidal horizontal cross-sectional shape.

The top surface of the conductive post 206 may contact the bottom surface of the second bottom surface connection pad 430P1, and the bottom surface of the conductive post 206 may contact the top surface of the first top surface connection pad 330P2.

The horizontal cross-sectional area of the conductive post 206 may vary. The horizontal cross-sectional area of the conductive post 206 may decrease toward the first top surface connection pad 330P2. For example, the conductive post 206 may have an inverted truncated cone-like shape, and the conductive post 206 may include a sidewall 206S inclined inward.

FIG. 4 is a flowchart of a method of manufacturing a semiconductor package, according to an embodiment.

Referring to FIG. 4, the method S10 of manufacturing a semiconductor package may include operations S110 to S190.

In a certain embodiment that may be implemented otherwise, particular operations may be performed in an order different from that described below. For example, two successively described operations may be performed substantially and simultaneously or may be performed in an order opposite to the order described below.

The method S10 of manufacturing a semiconductor package according to an embodiment may include operation S110 of forming a first wiring structure on a support substrate, operation S120 of coating a high transmittance photoresist PR on the first wiring structure, operation S130 of forming a plurality of openings by exposing and developing the high transmittance photoresist, operation S140 of forming a plurality of conductive posts by filling the plurality of openings with a conductive material, operation S150 of removing the high transmittance photoresist, operation S160 of mounting a first semiconductor chip on the first wiring structure, operation S170 of forming an encapsulant surrounding the first semiconductor chip and the plurality of conductive posts, operation S180 of forming a second wiring structure on the encapsulant, and operation S190 of mounting a second semiconductor chip on the second wiring structure.

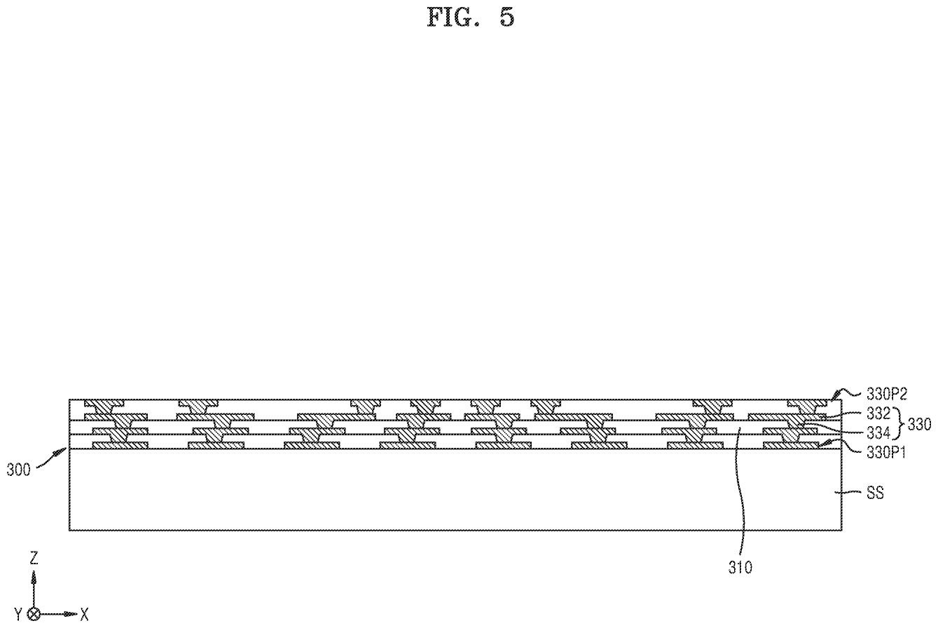

The technical features of operations S110 to S190 are described below in detail with reference to FIGS. 5 to 16.

FIGS. 5 to 16 are diagrams showing a method of manufacturing a semiconductor package according to an embodiment.

Referring to FIG. 5, the first wiring structure 300 including the plurality of first redistribution insulation layers 310 and the plurality of first redistribution patterns 330, which include the plurality of first redistribution line patterns 332 and the plurality of first redistribution vias 334, is formed on a support substrate SS.

The support substrate SS may be, for example, a semiconductor substrate, a glass substrate, a ceramic substrate, or a plastic substrate. In some embodiments, a release film may be attached onto the support substrate SS, and the first wiring structure 300 may be formed onto the release film.

The first redistribution line patterns 332 may be formed on the support substrate SS. The first redistribution line patterns 332 formed on the support substrate SS may include the plurality of first bottom surface connection pads 330P1.

After a first preliminary redistribution insulation layer covering the first redistribution line patterns 332 is formed on the support substrate SS, the first redistribution insulation layers 310 having a plurality of via holes may be formed by removing portions of the first preliminary redistribution insulation layer through an exposure process and a development process. The plurality of first via holes may each be formed, such that a horizontal width thereof decreases in a direction from the top surface of the first redistribution insulation layer 310 to the bottom surface of the first redistribution insulation layer 310. According to some embodiments, the plurality of first bottom surface connection pads 330P1 and the bottom surface of the lowermost first redistribution insulation layer 310 may be formed to be coplanar with each other.

After a first redistribution conductive layer is formed on the first redistribution insulation layer 310, the first redistribution conductive layer may be patterned, thereby forming the first redistribution patterns 330 including the first redistribution line patterns 332 and the first redistribution vias 334. The first redistribution vias 334 may be portions of the first redistribution patterns 330 that fill the plurality of first via holes, and the first redistribution line patterns 332 may be portions of the first redistribution patterns 330 above the top surface of the first redistribution insulation layers 310.

The first redistribution vias 334 may each be formed, such that a horizontal width thereof decreases in a direction from the top surface of the first redistribution insulation layer 310 to the bottom surface of the first redistribution insulation layer 310. Since the first redistribution patterns 330 including the first redistribution line patterns 332 and the first redistribution vias 334 are formed by patterning the first redistribution conductive layer, some of the first redistribution line patterns 332 formed on the first redistribution insulation layers 310 having the plurality of first via holes may be integrated with the first redistribution vias 334.

Next, the first wiring structure 300 may be formed by repeatedly forming the first redistribution insulation layers 310 and the first redistribution patterns 330. The first redistribution line patterns 332 formed to be arranged on the top surface of the first wiring structure 300 may be the plurality of first top surface connection pads 330P2. According to some embodiments, when the first wiring structure 300 may be formed to include a plurality of stacked first redistribution insulation layers 310, the plurality of first top surface connection pads 330P2 may be the first redistribution line patterns 332 formed to be arranged on the top surface of the uppermost first redistribution insulation layer 310. According to some embodiments, the top surface of the uppermost first redistribution insulation layer 310 and the top surface of the plurality of first top surface connection pads 330P2 may be formed to be coplanar.

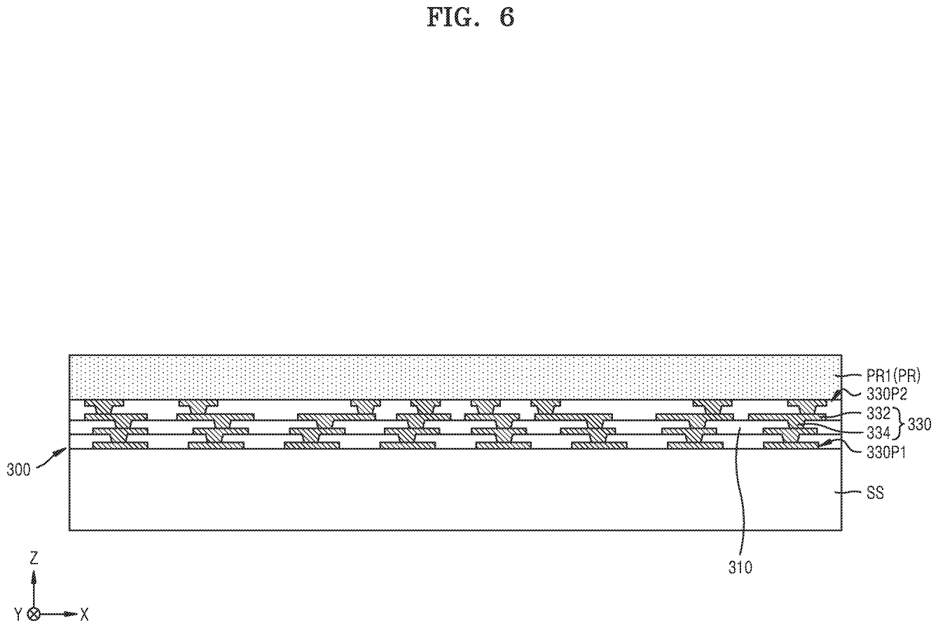

Referring to FIG. 6, a first photoresist layer PR1 is formed by coating and baking a high transmittance photoresist PR on the first wiring structure 300.

The high transmittance photoresist PR may be a negative photoresist. In general, a negative photoresist used for negative tone development may be a chemically amplified photoresist material. Here, an exposed portion, for example, a portion irradiated with light of or more than a threshold light amount, may remain, and a portion that is not exposed, for example, a portion not irradiated with light of or more than the threshold light amount, may be removed by a solvent. In the present disclosure, high transmittance may be a state in which light transmittance is greater than or equal to about 3% in all portions of a photoresist having a thickness greater than or equal to about 260 μm. Detailed descriptions on the light transmittance of the high transmittance photoresist PR according to an embodiment is given later.

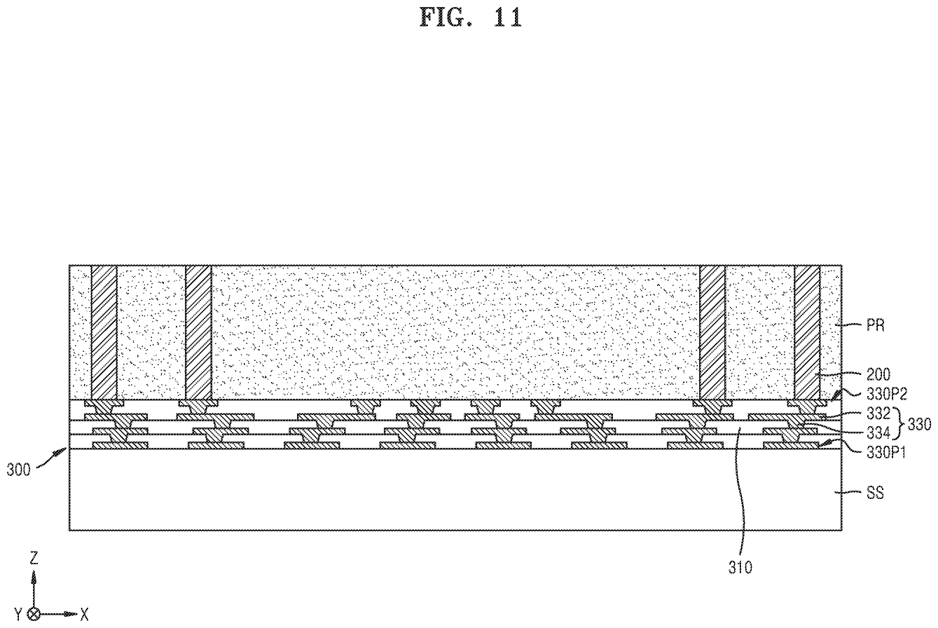

The first photoresist layer PR1 may be formed to have a thickness of about ⅓ of the total thickness of the high transmittance photoresist PR to be finally formed. As described above, to form the plurality of conductive posts 200 (refer to FIG. 11) having a high aspect ratio according to design rules through a single exposure process and a single development process, the high transmittance photoresist PR having a relatively large thickness is needed. However, since it is difficult to obtain a desired thickness through a single coating process, a method of forming a high transmittance photoresist PR through a plurality of coating processes may be used.

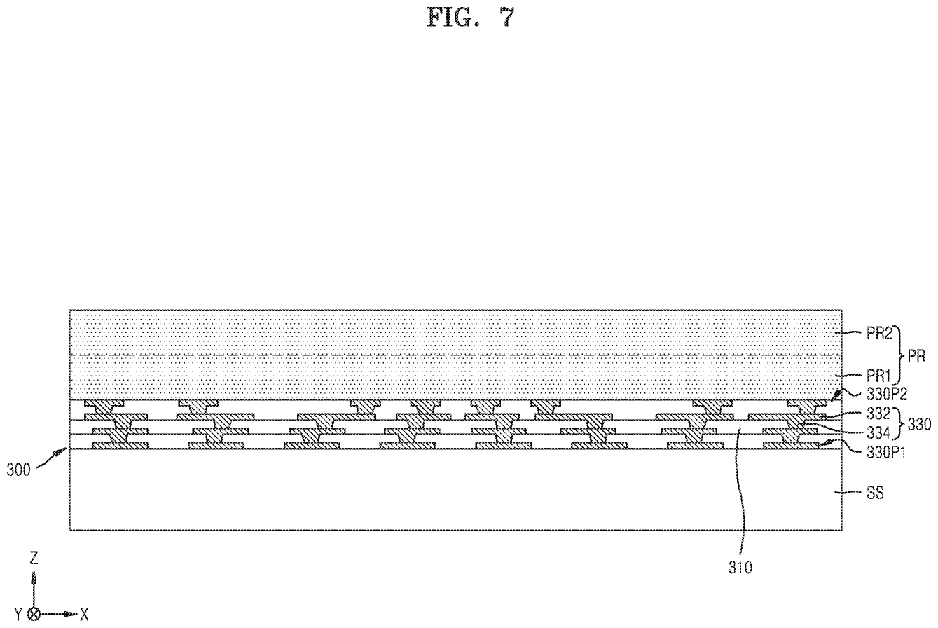

Referring to FIG. 7, a second photoresist layer PR2 is formed by applying and baking the same high transmittance photoresist PR on the previously formed first photoresist layer PR1.

Although the second photoresist layer PR2 and the first photoresist layer PR1 are formed in different order, the second photoresist layer PR2 may include substantially the same material as the first photoresist layer PR1. For example, the dashed line between the first photoresist layer PR1 and the second photoresist layer PR2 in the drawing is only for convenience of explanation and is not intended to divide the high transmittance photoresist PR.

Also, the second photoresist layer PR2 may be formed to have a thickness of about ⅓ of the total thickness of the high transmittance photoresist PR to be finally formed. Therefore, the first photoresist layer PR1 and the second photoresist layer PR2 may be formed to have a combined thickness of about ⅔ of the total thickness of the high transmittance photoresist PR to be finally formed.

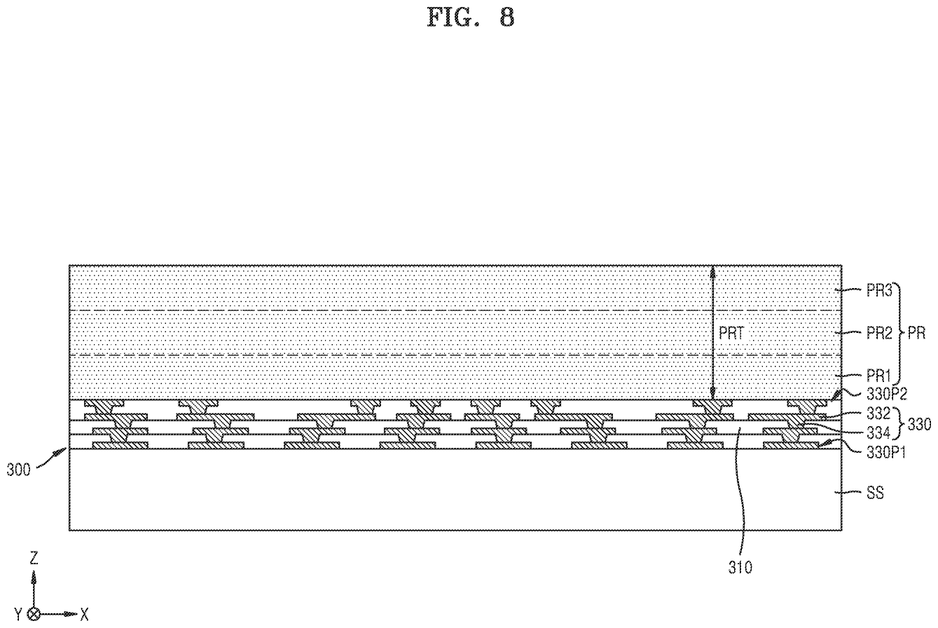

Referring to FIG. 8, a third photoresist layer PR3 is formed by applying and baking the same high transmittance photoresist PR on the previously formed second photoresist layer PR2.

Although the third photoresist layer PR3, the first photoresist layer PR1, and the second photoresist layer PR2 are formed in different order, the third photoresist layer PR3 may include substantially the same material as the first photoresist layer PR1 and the second photoresist layer PR2. For example, the dashed line between the second photoresist layer PR2 and the third photoresist layer PR3 in the drawing is only for convenience of explanation and is not intended to divide the high transmittance photoresist PR.

Also, the third photoresist layer PR3 may be formed to have a thickness of about ⅓ of a total thickness PRT of the high transmittance photoresist PR to be finally formed. Therefore, the first photoresist layer PR1, the second photoresist layer PR2, and the third photoresist layer PR3 may be formed to have a combined thickness equal to the total thickness PRT of the high transmittance photoresist PR to be finally formed. The total thickness PRT of the high transmittance photoresist PR may be from about 260 μm to about 500 μm, but is not limited thereto.

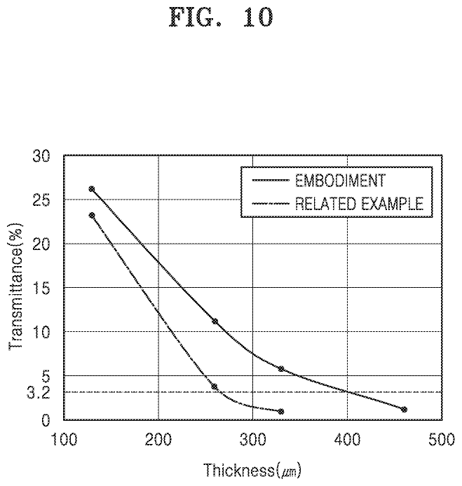

Referring to FIGS. 9 and 10 together, a plurality of openings OP are formed in the peripheral region of the first wiring structure 300 by exposing and developing the high transmittance photoresist PR.

Through an exposure process and a development process, the plurality of openings OP having a high aspect ratio may be regularly formed in the peripheral region of the first wiring structure 300. As described above, an exposure process and a development process may be performed by using the high transmittance photoresist PR to reduce a phenomenon in which the width of the bottom portion of the opening OP becomes excessively wider or narrower than an intended width.

In detail, the high transmittance photoresist PR may include a photosensitive material including resin, a photo-initiator (PI), a solvent, an additive, etc., wherein the content of the PI in the photosensitive material may be from about 5 wt % to about 13 wt %. For example, by reducing the content of the PI as compared to a general photoresist, a phenomenon in which transmission of light PL is suppressed by the PI may be reduced. In this regard, the high transmittance photoresist PR may increase the light transmittance as compared to a general photoresist.

For example, an environment in which the light PL of a certain amount or more may be transmitted to the first photoresist layer PR1 may be configured. For example, the content of the PI may be adjusted, such that the light transmittance of the high transmittance photoresist PR is greater than or equal to about 3.2% at a portion where the first wiring structure 300 and the first photoresist layer PR1 contact each other.

The graph of FIG. 10 is a graph of light transmittance (Y axis) measured from the bottom surface of a photoresist according to the thickness (X axis) of the photoresist. FIG. 10 shows that, by adjusting the content of the PI between about 5 wt % and about 13 wt %, the high transmittance photoresist PR according an embodiment exhibits high light transmittance even at a greater thickness than a general photoresist according to the related example. For example, it may be seen that the high transmittance photoresist PR according to the embodiment maintains a light transmittance of about 3.2% even at a thickness of about 400 om. However, in the case of a general photoresist according to the related example at the same thickness (X axis), it may be seen that the light transmittance thereof is too low to be measured.

In this regard, by maintaining a relatively high light transmittance even at the bottom surface of the high transmittance photoresist PR, the phenomenon that the width of the bottom portion of an opening OP having a relatively high aspect ratio becomes excessively wider or narrower than an intended width may be more efficiently suppressed.

Referring to FIG. 11, the plurality of conductive posts 200 electrically connected to the plurality of first top surface connection pads 330P2 arranged in an peripheral region are formed by filling the plurality of openings OP (refer to FIG. 9) with a conductive material.

The plurality of conductive posts 200 may be formed by using an electroplating method. According to the embodiment, the plurality of conductive posts 200 satisfying a desired shape may be formed through a single exposure process and a single development process by using a high transmittance photoresist PR and a single plating process according thereto. According to some embodiments, the conductive material may include copper (Cu) or a Cu alloy, but the embodiments are not limited thereto.

For example, the plurality of first top surface connection pads 330P2 may serve as seed layers for forming the plurality of conductive posts 200. For example, when the plurality of conductive posts 200 are formed through an electroplating process, the plurality of first top surface connection pads 330P2 provide a path through which currents may flow, and thus, the plurality of conductive posts 200 may be formed on the plurality of first top surface connection pads 330P2.

Through the process, the plurality of conductive posts 200 may have various shapes. Since embodiments of various shapes of the plurality of conductive posts 200 have been described above with reference to FIGS. 2A to 3C, detailed descriptions thereof are omitted below.

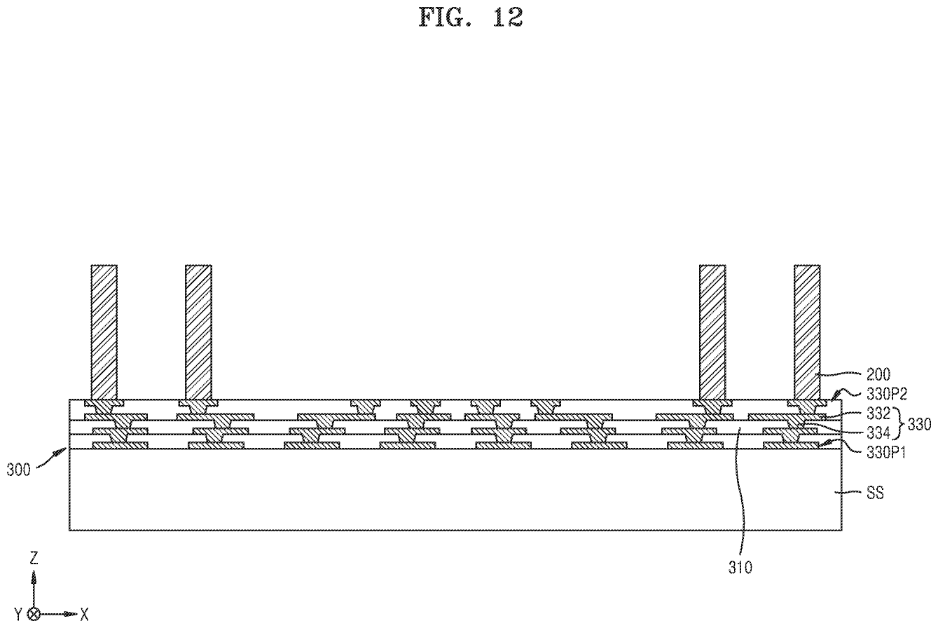

Referring to FIG. 12, after the plurality of conductive posts 200 are formed, the high transmittance photoresist PR (refer to FIG. 11) is removed.

A stripping process and/or an ashing process may be performed to remove the high transmittance photoresist PR (refer to FIG. 11). As the high transmittance photoresist PR (refer to FIG. 11) is removed, the plurality of conductive posts 200 may be arranged in the peripheral region of the first wiring structure 300 in various shapes as described above with reference to FIGS. 2A to 3C.

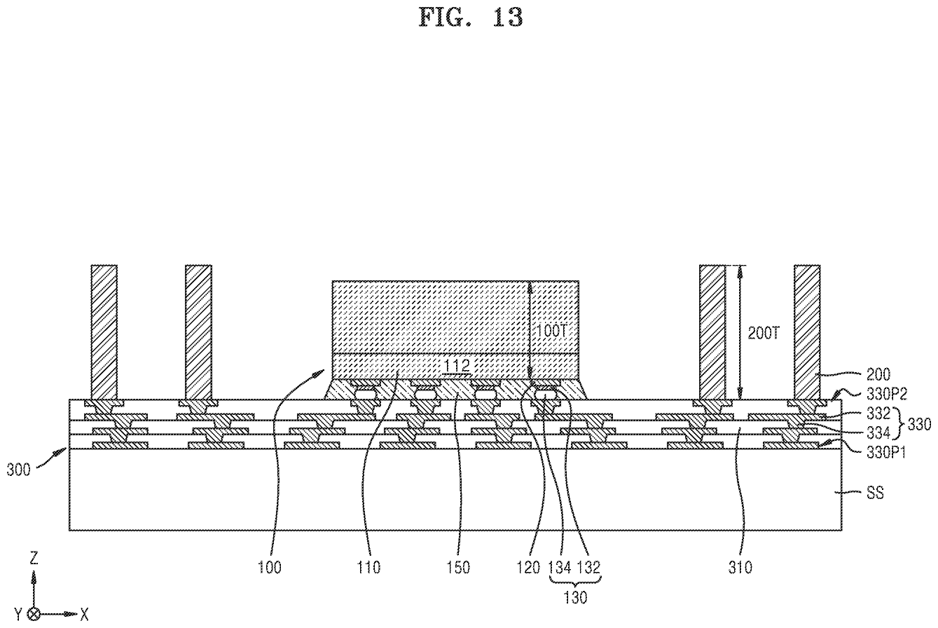

Referring to FIG. 13, the first semiconductor chip 100 including the plurality of chip pads 120 is mounted on the first wiring structure 300.

The first semiconductor chip 100 may be mounted on the first wiring structure 300, such that the plurality of chip connecting members 130 are provided between the plurality of chip pads 120 and some of the plurality of first top surface connection pads 330P2 of the first wiring structure 300.

The first semiconductor chip 100 may be mounted in a chip mounting region of the first wiring structure 300 to be spaced apart from the plurality of conductive posts 200 in a horizontal direction. For example, the plurality of chip connecting members 130 each including the UBM layer 132 and the conductive connection member 134 covering the UBM layer 132 are respectively formed on the plurality of chip pads 120 of the first semiconductor chip 100, and the first semiconductor chip 100 having formed thereon the plurality of chip connecting members 130 may be mounted on the first wiring structure 300.

The underfill layer 150 may be formed to fill a space between the first semiconductor chip 100 and the first wiring structure 300. The underfill layer 150 may be formed to surround the plurality of chip connecting members 130. According to some embodiments, the underfill layer 150 may be formed to fill a space between the first semiconductor chip 100 and the first wiring structure 300 and may cover lower portions of side surfaces of the first semiconductor chip 100.

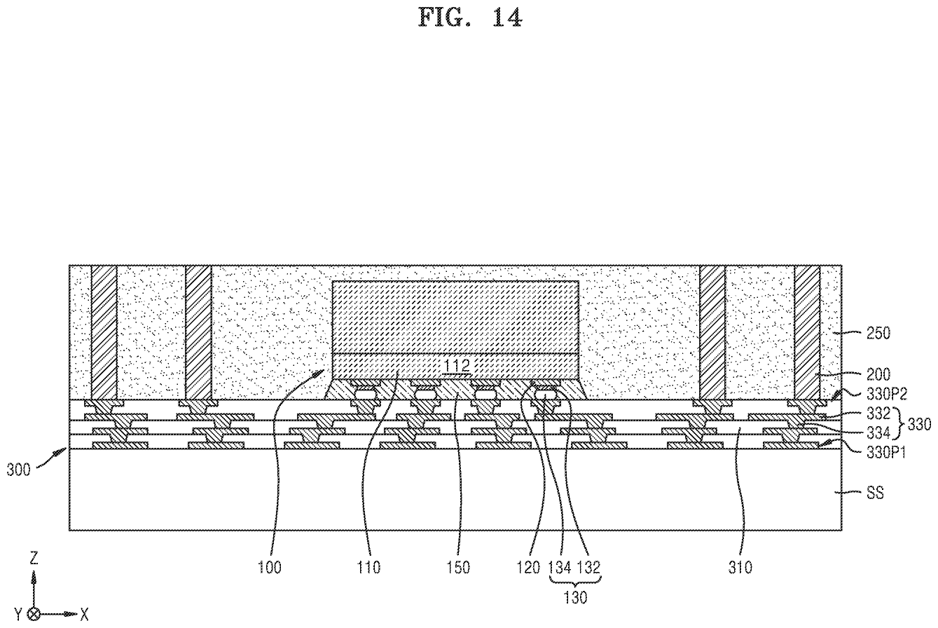

Referring to FIG. 14, the encapsulant 250 is formed to cover the first semiconductor chip 100 and the plurality of conductive posts 200.

To cover the top surfaces of all of the plurality of conductive posts 200, the encapsulant 250 may be formed to have a top surface that is at a higher vertical level than a vertical level of the top surface of the plurality of conductive posts 200.

Next, a portion of the encapsulant 250 is removed to expose the plurality of conductive posts 200. For example, a portion of the upper portion of the encapsulant 250 may be removed through a chemical mechanical polishing (CMP) process. The encapsulant 250 may include a molding member containing an EMC.

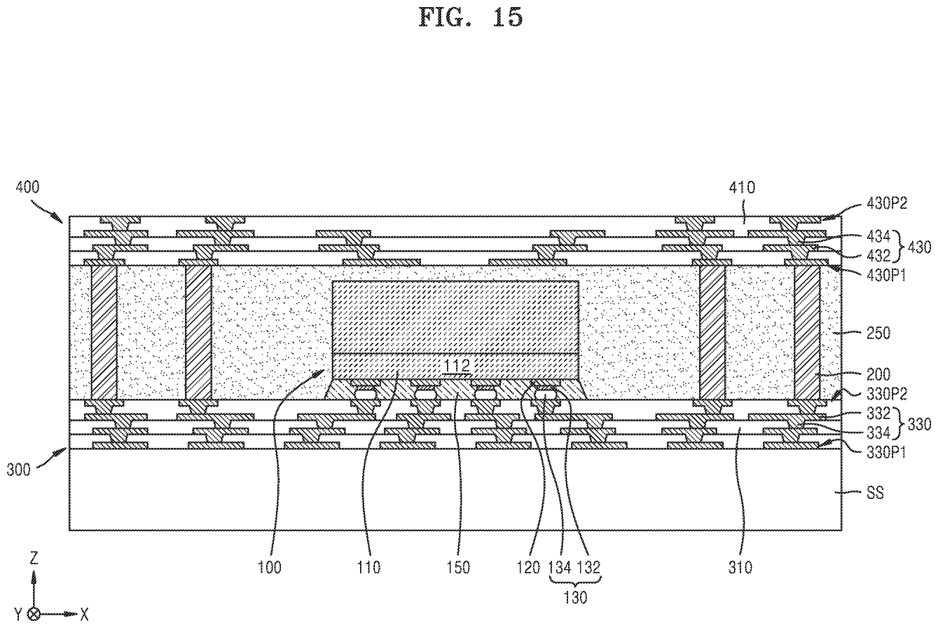

Referring to FIG. 15, the second wiring structure 400 including the second redistribution insulation layer 410 and the plurality of second redistribution patterns 430, which include the plurality of second redistribution line patterns 432 and the plurality of second redistribution vias 434, is formed on the plurality of conductive posts 200 and the encapsulant 250.

After a second preliminary redistribution insulation layer is formed on the plurality of conductive posts 200 and the encapsulant 250, a portion of the second preliminary redistribution insulation layer may be removed through an exposure process and a development process, thereby forming a plurality of second redistribution insulation layers 410 having a plurality of second via holes.

The plurality of second via holes may each be formed, such that a horizontal width thereof decreases in a direction from the top surface of the second redistribution insulation layer 410 to the bottom surface of the second redistribution insulation layer 410. After a second redistribution conductive layer is formed on the second redistribution insulation layer 410, the second redistribution conductive layer may be patterned, thereby forming the second redistribution patterns 430 including the second redistribution line patterns 432 and the second redistribution vias 434.

The second redistribution vias 434 formed on the plurality of conductive posts 200 may be the plurality of second bottom surface connection pads 430P1. The second redistribution vias 434 may be portions of the second redistribution patterns 430 that fill the plurality of second via holes, and the second redistribution line patterns 432 may be portions of the second redistribution patterns 430 above the top surface of the second redistribution insulation layers 410. The second redistribution vias 434 may each be formed, such that a horizontal width thereof decreases in a direction from the top surface of the second redistribution insulation layer 410 to the bottom surface of the second redistribution insulation layer 410. Since the second redistribution patterns 430 including the second redistribution line patterns 432 and the second redistribution vias 434 are formed by patterning the second redistribution conductive layer, some of the second redistribution line patterns 432 formed on the second redistribution insulation layers 410 having the plurality of second via holes may be integrated with the second redistribution vias 434.

Next, the second wiring structure 400 may be formed by repeatedly forming the second redistribution insulation layers 410 and the second redistribution patterns 430. According to some embodiments, the bottom surfaces of the plurality of second bottom surface connection pads 430P1 and the bottom surface of the lowermost second redistribution insulation layer 410 may be formed to be coplanar with each other.

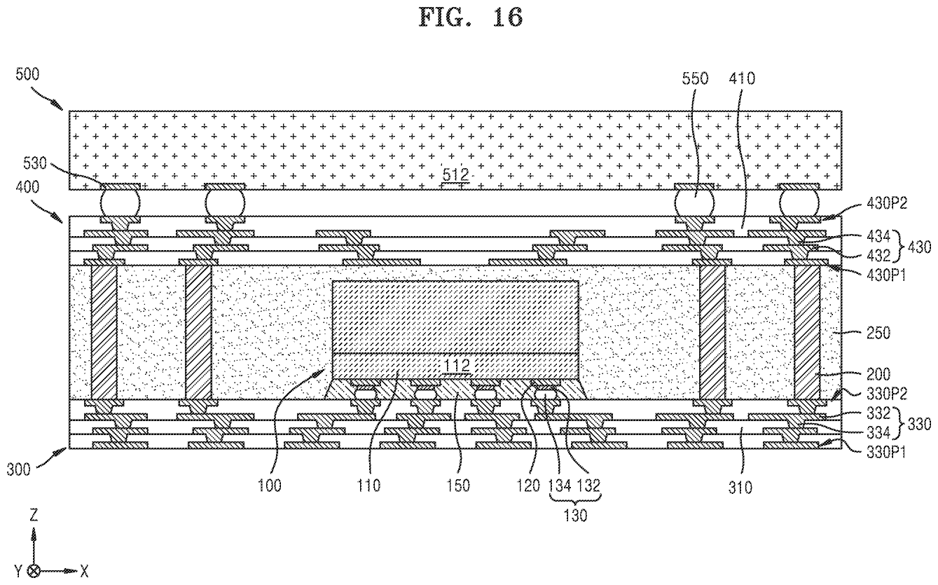

Referring to FIG. 16, the second semiconductor chip 500 is mounted to be electrically connected to the second wiring structure 400.

The second semiconductor chip 500 may be mounted on the second wiring structure 400, such that the plurality of upper connection pads 530 face the second wiring structure 400.

According to some embodiments, the second semiconductor chip 500 may be electrically connected to the plurality of first redistribution patterns 330 of the first wiring structure 300 through the plurality of internal connection terminals 550 attached to the plurality of upper connection pads 530, the plurality of second redistribution patterns 430, and the plurality of conductive posts 200.

Referring back to FIG. 1, the semiconductor package 10 may be completed by attaching the plurality of external connection terminals 600 to the plurality of first bottom surface connection pads 330P1.

As described above, according to the method of manufacturing a semiconductor package according to embodiments, by using a high transmittance photoresist PR (refer to FIG. 9), the plurality of conductive posts 200 having a high aspect ratio may be formed precisely according to design rules through a single exposure process, a single development process, and a single plating process.

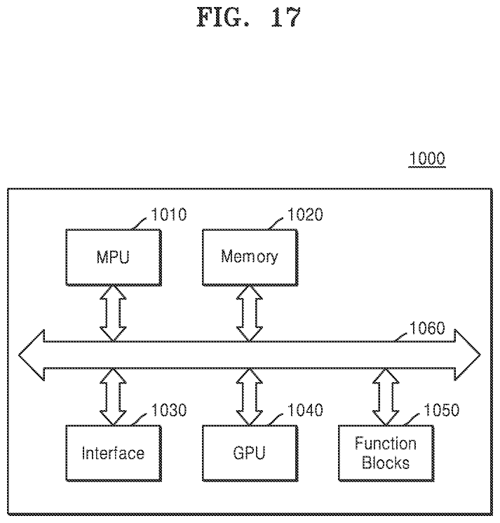

FIG. 17 is a diagram schematically showing a configuration of a semiconductor package according to an embodiment.

Referring to FIG. 17, a semiconductor package 1000 may include a microprocessor 1010, a memory 1020, an interface 1030, a graphics processing unit 1040, functional blocks 1050, and a bus 1060 connecting them to one another.

The semiconductor package 1000 may include both the microprocessor 1010 and the graphics processing unit 1040 or may include only one of them.

The microprocessor 1010 may include a core and a cache. For example, the microprocessor 1010 may include multi-cores. Cores of the multi-cores may have performance same as or different from one another. Also, the core of the multi-cores may be activated at the same time or may be activated at different times.

The memory 1020 may store results processed by the functional blocks 1050 under the control of the microprocessor 1010. The interface 1030 may exchange information or signals with external devices. The graphics processing unit 1040 may perform graphic functions. For example, the graphics processing unit 1040 may execute a video codec or process three dimensional (3D) graphics. The functional blocks 1050 may perform various functions. For example, when the semiconductor package 1000 is an application processor used in a mobile device, some of the functional blocks 1050 may perform a communication function.

The semiconductor package 1000 may include the semiconductor package 10 described above with reference to FIG. 1 and/or a semiconductor package manufactured according to the method S10 of manufacturing a semiconductor package described above with reference to FIG. 4.

While embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing a semiconductor package, the method comprising:
forming a first wiring structure, comprising a plurality of first wiring patterns that comprise a plurality of first connection pads, and a first insulation layer surrounding the plurality of first wiring patterns, the first wiring structure comprising a chip mounting region and a peripheral region adjacent to the chip mounting region;
coating a high transmittance photoresist on the first wiring structure a plurality of number of times;
forming a plurality of openings in the peripheral region by exposing and developing the high transmittance photoresist;
forming a plurality of conductive posts connected to the plurality of first connection pads in the peripheral region by filling the plurality of openings with a conductive material;
removing the high transmittance photoresist;
disposing a semiconductor chip in the chip mounting region on the first wiring structure;
forming an encapsulant surrounding the semiconductor chip and the plurality of conductive posts; and
forming a second wiring structure on the encapsulant, the second wiring structure comprising a plurality of second wiring patterns that comprise a plurality of second connection pads electrically connected to the plurality of conductive posts and a second insulation layer surrounding the plurality of second wiring patterns,
wherein light transmittance of the high transmittance photoresist is equal to or greater than 3.2% at a portion where the first wiring structure contacts the high transmittance photoresist.

2. The method of claim 1, wherein, in the coating of the high transmittance photoresist a number of times, a total thickness of the high transmittance photoresist is 260 μm to 500 μm.

3. The method of claim 2, wherein the coating of the high transmittance photoresist the plurality of number of times comprises:
first coating and baking a first high transmittance photoresist on the first wiring structure;
second coating and baking a second high transmittance photoresist on the first high transmittance photoresist; and
third coating and baking a third high transmittance photoresist on the second high transmittance photoresist,
wherein the first high transmittance photoresist, the second high transmittance photoresist, and the third high transmittance photoresist comprise a same photoresist material.

4. The method of claim 1, wherein the high transmittance photoresist comprises a negative photoresist.

5. The method of claim 4, wherein the high transmittance photoresist comprises a chemically amplified photoresist material comprising resin, a photoinitiator, a solvent, and an additive, and,
wherein percentage by weight of the photoinitiator included in the chemically amplified photoresist material is from 5 wt % to 13 wt %.

6. The method of claim 1, wherein, in the forming of the plurality of conductive posts, the plurality of openings are all filled with the conductive material through a single plating process.

7. The method of claim 6, wherein each of the plurality of conductive posts comprises a body portion having a constant horizontal cross-sectional area and a bottom portion having a varying horizontal cross-sectional area,
wherein a top surface of the body portion has a first diameter,
wherein a bottom surface of the bottom portion has a second diameter, and
wherein the second diameter is greater than the first diameter and less than 1.3 times the first diameter.

8. The method of claim 7, wherein a rate of change of the horizontal cross-sectional area of the bottom portion in a vertical direction is constant.

9. The method of claim 7, wherein a rate of change of the horizontal cross-sectional area of the bottom portion in a vertical direction decreases in a direction toward the first wiring structure.

10. The method of claim 6, wherein each of the plurality of conductive posts comprises a body portion having a constant horizontal cross-sectional area and a bottom portion having a varying horizontal cross-sectional area,
wherein a top surface of the body portion has a first diameter,
wherein a bottom surface of the bottom portion has a second diameter, and
wherein the second diameter is greater than 0.7 times the first diameter and less than the first diameter.

11. A method of manufacturing a semiconductor package, the method comprising:
forming a first wiring structure comprising a chip mounting region and a peripheral region adjacent to the chip mounting region;
forming a first photoresist layer by first coating and baking a high transmittance photoresist on the first wiring structure;
forming a second photoresist layer by second coating and baking the high transmittance photoresist on the first photoresist layer;
forming a third photoresist layer by third coating and baking the high transmittance photoresist on the second photoresist layer;
forming a plurality of openings in the peripheral region by exposing and developing the first photoresist layer, the second photoresist layer, and the third photoresist layer;
forming a plurality of conductive posts by filling the plurality of openings with a conductive material through a single plating process;
removing the first photoresist layer, the second photoresist layer, and the third photoresist layer;
disposing a semiconductor chip in the chip mounting region on the first wiring structure;
forming an encapsulant surrounding the semiconductor chip and the plurality of conductive posts; and
forming a second wiring structure on the encapsulant,
wherein light transmittance of the first photoresist layer is greater than or equal to 3.2% at a portion where the first wiring structure contacts the first photoresist layer.

12. The method of claim 11, wherein a total thickness of the first photoresist layer, the second photoresist layer, and the third photoresist layer is from 260 μm to 500 μm.

13. The method of claim 12, wherein a height of the plurality of conductive posts is at least 200 μm, and
wherein an aspect ratio of the plurality of conductive posts is greater than or equal to 1.

14. The method of claim 11, wherein the high transmittance photoresist comprises a negative photoresist material comprising resin, a photoinitiator, a solvent, and an additive, and,
wherein percentage by weight of the photoinitiator is from 5 wt % to 13 wt % in the negative photoresist material.

15. The method of claim 11, wherein each of the plurality of conductive posts comprises a body portion having a constant horizontal cross-sectional area and a bottom portion having a varying horizontal cross-sectional area, and
wherein a rate of change of the horizontal cross-sectional area of the bottom portion in a vertical direction decreases in a direction toward the first wiring structure.

16. A semiconductor package comprising:
a first redistribution structure comprising:
a plurality of first redistribution patterns comprising a plurality of first bottom surface connection pads and a plurality of first top surface connection pads; and
a first redistribution insulation layer surrounding the plurality of first redistribution patterns;
a first semiconductor chip on a first chip mounting region on the first redistribution structure;
a second redistribution structure on the first semiconductor chip and the first redistribution structure, the second redistribution structure comprising:
a plurality of second redistribution patterns comprising a plurality of second bottom surface connection pads and a plurality of second top surface connection pads; and
a second redistribution insulation layer surrounding the plurality of second redistribution patterns;
a second semiconductor chip on a second chip mounting region on the second redistribution structure;
a plurality of conductive posts adjacent to the first semiconductor chip and connecting some of the plurality of first top surface connection pads to some of the plurality of second bottom surface connection pads; and
an encapsulant filling a space between the first redistribution structure and the second redistribution structure and surrounding the plurality of conductive posts and the first semiconductor chip,
wherein each of the plurality of conductive posts comprises:
a body portion having a constant horizontal cross-sectional area; and
a bottom portion having a varying horizontal cross-sectional area, and
wherein a top surface of the body portion has a first diameter and a bottom surface of the bottom portion has a second diameter that is different from the first diameter.

17. The semiconductor package of claim 16, wherein a total height of the plurality of conductive posts is greater than or equal to 200 μm,
wherein an aspect ratio of the plurality of conductive posts is greater than or equal to 1, and
wherein the second diameter is greater than the first diameter and less than 1.3 times the first diameter.

18. The semiconductor package of claim 16, wherein a total height of the plurality of conductive posts is greater than or equal to 200 pin,
wherein the plurality of conductive posts are formed through a single plating process, and
wherein the second diameter is greater than 0.7 times the first diameter and less than the first diameter.

19. The semiconductor package of claim 16, wherein a rate of change of the horizontal cross-sectional area of the bottom portion in a vertical direction is constant.

20. The semiconductor package of claim 16, wherein a rate of change of the horizontal cross-sectional area of the bottom portion in a vertical direction decreases in a direction toward the first redistribution structure.
